(19) United States
(12) Patent Application Publication
(10) Pub. No.: US 2023/0230897 A1
(43) Pub. Date: Jul. 20, 2023

(54) AUTOMOBILE HEAT DISSIPATION DEVICE HAVING MODIFIED SURFACE AND SURFACE MODIFICATION AND JOINT METHOD FOR AUTOMOBILE HEAT DISSIPATION DEVICE

(71) Applicant: AMULAIRE THERMAL TECHNOLOGY, INC., New Taipei City (TW)

(72) Inventors: YI-HSIN HUANG, New Taipei City (TW); CHING-MING YANG, New Taipei City (TW); TZE-YANG YEH, New Taipei City (TW)

(21) Appl. No.: 17/577,243

(22) Filed: Jan. 17, 2022

(51) Int. Cl. H01L 23/373

(52) U.S. Cl. CPC H01L 23/3736; H01L 2224/8384

(57) ABSTRACT

A surface modification and joint method for an automobile heat dissipation device and an automobile heat dissipation device having a modified surface are provided. The surface modification and joint method includes providing a metal heat dissipation device, forming a sputtered metal layer that is patterned on a surface of the metal heat dissipation device by sputtering to form a modification area of the metal heat dissipation device so as to modify the surface of the metal heat dissipation device, and jointing a surface of the sputtered metal layer to at least one automobile electronic module by sintering, so that the metal heat dissipation device is thermally coupled to the at least one automobile electronic module.

### FIELD OF THE DISCLOSURE

The present disclosure relates to an automobile heat dissipation device, and more particularly to a surface modification and joint method for an automobile heat dissipation device and an automobile heat dissipation device having a modified surface.

### BACKGROUND OF THE DISCLOSURE

High heat is often generated during operation of conventional automobile electronic modules, such as insulated gate bipolar transistor (IGBT) modules and advanced driver-assistance system (ADAS) modules. If proper heat dissipation measures are not adopted, temperature of the automobile electronic modules may exceed allowable temperature, which results in deterioration of performance and damage thereof.

### SUMMARY OF THE DISCLOSURE

In response to the above-referenced technical inadequacy, the present disclosure provides a surface modification and joint method for an automobile heat dissipation device and an automobile heat dissipation device having a modified surface.

In one aspect, the present disclosure provides a surface modification and joint method for an automobile heat dissipation device, and the surface modification and joint method includes (a) providing a metal heat dissipation device, (b) forming a sputtered metal layer that is patterned on a surface of the metal heat dissipation device by sputtering to form a modification area of the metal heat dissipation device, so as to modify the surface of the metal heat dissipation device, and (c) jointing a surface of the sputtered metal layer to at least one automobile electronic module by sintering, so that the metal heat dissipation device is thermally coupled to the at least one automobile electronic module.

In certain embodiments, a fin structure is disposed in the metal heat dissipation device.

In certain embodiments, the metal heat dissipation device is a water-cooled metal heat dissipation device or an air-cooled metal heat dissipation device.

In certain embodiments, the metal heat dissipation device is a closed metal heat dissipation device or a semi-open metal heat dissipation device.

In certain embodiments, the metal heat dissipation device is made of at least one of aluminum, aluminum alloy, copper, and copper alloy.

In certain embodiments, the sputtered metal layer is made of nickel, nickel alloy, copper, copper alloy, silver, or silver alloy.

In certain embodiments, in step (c), at least one sintered layer is formed on the surface of the sputtered metal layer to be jointed to the at least one automobile electronic module.

In certain embodiments, the sintered layer is a copper sintered layer formed by copper or copper alloy of a sintering paste.

In certain embodiments, the sintered layer is a silver sintered layer formed by silver or silver alloy of a sintering paste.

In certain embodiments, in step (b), at least one masking area is formed on the surface of the metal heat dissipation device by a masking process, so that the sputtered metal layer is not formed in the at least one masking area, and the sputtered metal layer that is patterned is formed on the surface of the metal heat dissipation device.

In certain embodiments, the automobile electronic module is an insulated gate bipolar transistor (IGBT) module or an advanced driver-assistance system (ADAS) module.

In another aspect, the present disclosure provides an automobile heat dissipation device having a modified surface. The automobile heat dissipation device includes a metal heat dissipation device, a sputtered metal layer, and a sintered layer. The sputtered metal layer is formed on a surface of the metal heat dissipation device by sputtering to form a modification area of the metal heat dissipation device, so as to modify the surface of the metal heat dissipation device. The sintered layer is formed between the sputtered metal layer and at least one automobile electronic module by sintering, so that the metal heat dissipation device is thermally coupled to the at least one automobile electronic module.

Therefore, one of the beneficial effects of the present disclosure is that, in the surface modification and joint method for the automobile heat dissipation device and the automobile heat dissipation device having the modified surface, by virtue of “providing the metal heat dissipation device,” “forming the sputtered metal layer that is patterned on the surface of the metal heat dissipation device by sputtering to form the modification area of the metal heat dissipation device, so as to modify the surface of the metal heat dissipation device,” and “jointing the surface of the sputtered metal layer to at least one automobile electronic module by sintering, so that the metal heat dissipation device is thermally coupled to the at least one automobile electronic module,” the metal heat dissipation device can be thermally coupled to the at least one automobile electronic module through the formation of the modification area and the joint manner of sintering, thereby improving bonding strength, electrical conductivity, and thermal conductivity.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a metal heat dissipation device according to one embodiment of the present disclosure;

FIG. 2 is a schematic side view of the metal heat dissipation device having a masking area and a modification area formed on a surface thereof according to one embodiment of the present disclosure; and

FIG. 3 is a schematic side view of the metal heat dissipation device thermally coupled to an automobile electronic module according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Embodiments

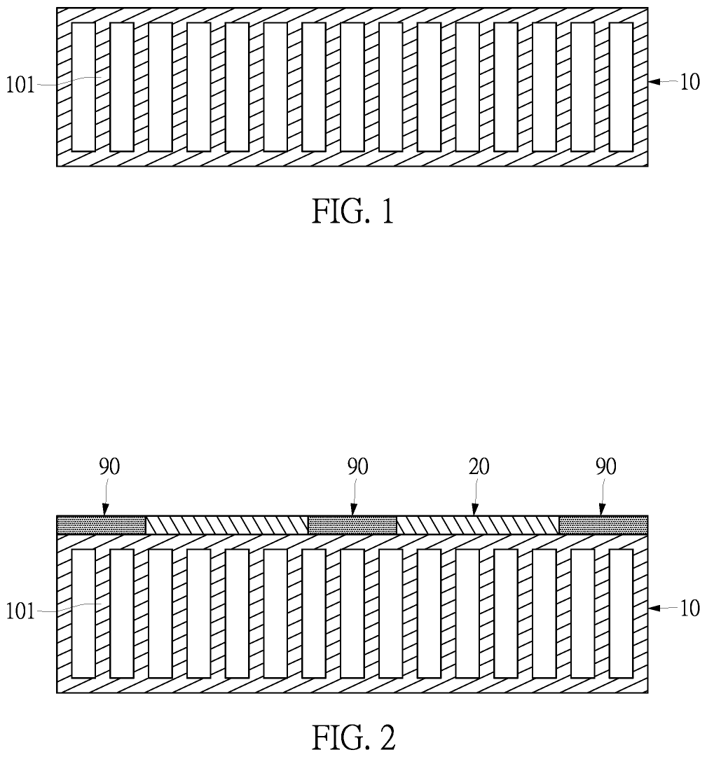

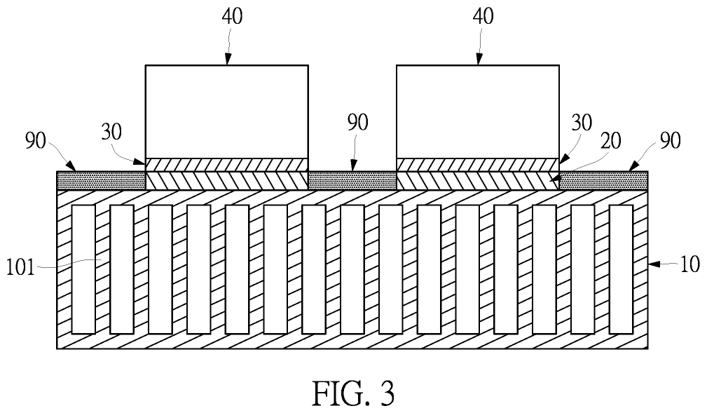

Referring to FIG. 1 to FIG. 3, embodiments of the present disclosure provide a surface modification and joint method for an automobile heat dissipation device, which includes the following steps.

In step (a), a metal heat dissipation device 10 is provided. Further, in the present embodiment, a fin structure 101 is disposed in the metal heat dissipation device 10, and the fin structure 101 can be a plate fin or a pin fin, but is not limited thereto. Furthermore, the metal heat dissipation device 10 can be a water-cooled metal heat dissipation device or an air-cooled metal heat dissipation device, or be a closed metal heat dissipation device or a semi-open metal heat dissipation device. Further, the metal heat dissipation device 10 can be made of at least one of aluminum, aluminum alloy, copper, and copper alloy.

In step (b), a sputtered metal layer 20 that is patterned is formed on a surface of the metal heat dissipation device 10 by sputtering to form a modification area of the metal heat dissipation device 10, so as to modify the surface of the metal heat dissipation device 10. Further, at least one masking area 90 is formed on the surface of the metal heat dissipation device 10 by a masking process, such as by arranging a masking jig on the surface of the metal heat dissipation device 10, by printing ink on the surface of the metal heat dissipation device 10, and by arranging an electroplating tape on the surface of the metal heat dissipation device 10, so that a metal layer is not formed in the at least one masking area 90, thereby forming the sputtered metal layer 20 that is patterned on the surface of the metal heat dissipation device 10.

In one embodiment, the sputtered metal layer 20 can be formed by sputtering a single metal. The single metal can be nickel, copper, or silver. Therefore, the sputtered metal layer 20 can be a sputtered nickel layer, a sputtered copper layer, or a sputtered silver layer. In addition, a thickness of the metal sputtered layer 20 is preferably between 1 μm and 5 μm.

In one embodiment, the sputtered metal layer 20 can be formed by sputtering an alloy metal. The alloy metal can be nickel alloy, copper alloy, or silver alloy. Therefore, the sputtered metal layer 20 can also be a sputtered nickel alloy layer, a sputtered copper alloy layer, or a sputtered silver alloy layer.

In step (c), a surface of the sputtered metal layer 20 is jointed to at least one automobile electronic module 40 by sintering, so that the metal heat dissipation device 10 is thermally coupled to the at least one automobile electronic module 40. Further, in step (c), at least one sintered layer 30 is formed on the surface of the sputtered metal layer 20 to be jointed to the at least one automobile electronic module 40. In addition, the sintered layer 30 can be a copper sintered layer formed by sintering paste of copper or copper alloy or a silver sintered layer formed by sintering paste of silver or silver alloy. Moreover, the at least one automobile electronic module 40 can be an insulated gate bipolar transistor (IGBT) module or an advanced driver-assistance system (ADAS) module. Therefore, through forming the modification area that is formed by the sputtered metal layer 20 on the surface of the metal heat dissipation device 10, the modification area has a different property from that of other areas, so that the metal heat dissipation device 10 can be thermally coupled to the at least one automobile electronic module 40 through the formation of the modification area and the joint manner of sintering, thereby improving bonding strength, electrical conductivity, and thermal conductivity.

Furthermore, according to the above, the embodiments of the present disclosure also provide an automobile heat dissipation device having a modified surface. The automobile heat dissipation device includes a metal heat dissipation device 10, a sputtered metal layer 20, a sintered layer 30, and an automobile electronic module 40. Further, the sputtered metal layer 20 is formed on a surface of the metal heat dissipation device 10 by sputtering to form a modification area of the metal heat dissipation device 10, so as to modify the surface of the metal heat dissipation device 10. In addition, the sintered layer 30 is formed between the sputtered metal layer 20 and the automobile electronic module 40 by sintering, so that the metal heat dissipation device 10 is thermally coupled to the automobile electronic module 40.

In one embodiment, the metal heat dissipation device 10 can have a fin structure 101 disposed therein. The metal heat dissipation device 10 can be a water-cooled metal heat dissipation device or an air-cooled metal heat dissipation device. The metal heat dissipation device 10 can be a closed metal heat dissipation device or a semi-open metal heat dissipation device. In addition, the metal heat dissipation device 10 can be made of at least one of aluminum, aluminum alloy, copper, and copper alloy.

In one embodiment, the sputtered metal layer 20 can be made of nickel, nickel alloy, copper, copper alloy, silver, or silver alloy.

In one embodiment, the sintered layer 30 can be a copper sintered layer formed by copper or copper alloy of a sintering paste or a silver sintered layer formed by silver or silver alloy of a sintering paste.

In one embodiment, the automobile electronic module 40 can be an insulated gate bipolar transistor (IGBT) module or an advanced driver-assistance system (ADAS) module.

### Beneficial Effects of the Embodiments

In conclusion, in the surface modification and joint method for the automobile heat dissipation device and the automobile heat dissipation device having the modified surface, by virtue of “providing the metal heat dissipation device 10,” “forming the sputtered metal layer that is patterned on the surface of the metal heat dissipation device 10 by sputtering to form the modification area of the metal heat dissipation device 10, so as to modify the surface of the metal heat dissipation device 10,” and “jointing the surface of the sputtered metal layer 20 to at least one automobile electronic module 40 by sintering, so that the metal heat dissipation device 10 is thermally coupled to the at least one automobile electronic module 40,” the metal heat dissipation device 10 can be thermally coupled to the at least one automobile electronic module 40 through the formation of the modification area and the joint manner of sintering, thereby improving the bonding strength, the electrical conductivity, and the thermal conductivity.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A surface modification and joint method for an automobile heat dissipation device, comprising:
(a) providing a metal heat dissipation device;
(b) forming a sputtered metal layer that is patterned on a surface of the metal heat dissipation device by sputtering to form a modification area of the metal heat dissipation device, so as to modify the surface of the metal heat dissipation device; and
(c) jointing a surface of the sputtered metal layer to at least one automotive electronic module by sintering, so that the metal heat dissipation device is thermally coupled to the at least one automobile electronic module.

2. The surface modification and joint method according to claim 1, wherein a fin structure is disposed in the metal heat dissipation device.

3. The surface modification and joint method according to claim 2, wherein the metal heat dissipation device is a water-cooled metal heat dissipation device or an air-cooled metal heat dissipation device.

4. The surface modification and joint method according to claim 2, wherein the metal heat dissipation device is a closed metal heat dissipation device or a semi-open metal heat dissipation device.

5. The surface modification and joint method according to claim 2, wherein the metal heat dissipation device is made of at least one of aluminum, aluminum alloy, copper, and copper alloy.

6. The surface modification and joint method according to claim 1, wherein the sputtered metal layer is made of nickel, nickel alloy, copper, copper alloy, silver, or silver alloy.

7. The surface modification and joint method according to claim 1, wherein in step (c), at least one sintered layer is formed on the surface of the sputtered metal layer to be jointed to the at least one automobile electronic module.

8. The surface modification and joint method according to claim 7, wherein the sintered layer is a copper sintered layer formed by copper or copper alloy of a sintering paste.

9. The surface modification and joint method according to claim 7, wherein the sintered layer is a silver sintered layer formed by silver or silver alloy of a sintering paste.

10. The surface modification and joint method according to claim 1, wherein in step (b), at least one masking area is formed on the surface of the metal heat dissipation device by a masking process, so that the sputtered metal layer is not formed in the at least one masking area, and the sputtered metal layer that is patterned is formed on the surface of the metal heat dissipation device.

11. The surface modification and joint method according to claim 1, wherein the automobile electronic module is an insulated gate bipolar transistor (IGBT) module or an advanced driver-assistance system (ADAS) module.

12. An automobile heat dissipation device having a modified surface, comprising:
a metal heat dissipation device;
a sputtered metal layer formed on a surface of the metal heat dissipation device by sputtering to form a modification area of the metal heat dissipation device so as to modify the surface of the metal heat dissipation device; and
a sintered layer formed between the sputtered metal layer and at least one automobile electronic module by sintering, so that the metal heat dissipation device is thermally coupled to the at least one automobile electronic module.
